(19) United States
(12) Patent Application Publication
(10) Pub. No.: US 2025/0285896 A1
(43) Pub. Date: Sep. 11, 2025

(54) DETECTION EQUIPMENT AND DETECTION METHOD

(71) Applicant: SILICONWARE PRECISION INDUSTRIES CO., LTD., Taichung City (TW)

(72) Inventors: Kai-Chao CHUANG, Taichung City (TW); Cheng-Yu CHIU, Taichung City (TW); Shih-Hua CHANG, Taichung City (TW); Chia-Kai CHANG, Taichung City (TW); Ming-Wei LAI, Taichung City (TW)

(73) Assignee: SILICONWARE PRECISION INDUSTRIES CO., LTD., Taichung City (TW)

(21) Appl. No.: 18/775,965

(22) Filed: Jul. 17, 2024

(30) Foreign Application Priority Data
Mar. 6, 2024 (TW) 113108176

(51) Int. Cl. H01L 21/67; G01J 3/50; H01L 21/677

(52) U.S. Cl. CPC H01L 21/67294; G01J 3/50; H01L 21/67706

(57) ABSTRACT

A detection equipment and a detection method for detecting whether a semiconductor device is provided with a patch, wherein multiple light sources are used to perform color analysis and sampling of the patch via a color sensor, so as to identify the patch by using a proportion of light and color components reflected by the patch, and a control device is used to receive an activation signal of the color sensor and generating a detection value, wherein if the detection value is greater than a preset value, it is determined that the semiconductor device is provided with a patch, and wherein if the detection value is less than the preset value, it is determined that the semiconductor device is not provided with a patch.

### BACKGROUND

### 1. Technical Field

The present disclosure relates to a detection equipment and a detection method, and more particularly, to a detection equipment and a detection method applied to semiconductor devices.

### 2. Description of Related Art

A traditional semiconductor package that uses a lead frame as a die carrier,

such as a Quad Flat Non-leaded (QFN) semiconductor package 1 shown in FIG. 1 is made as follows: bonding a semiconductor die 11 on a lead frame 10 having a die pad 100 and a plurality of leads 101, electrically connecting the semiconductor die 11 and the plurality of leads 101 via a plurality of bonding wires 12, covering the semiconductor die 11 and the bonding wires 12 with an encapsulating colloid 13, and exposing a surface of the die pad 100 from the encapsulating colloid 13 to allow the die pad 100 to accelerate the dissipation of heat on the semiconductor die 11.

However, when forming the encapsulating colloid 13, if the lower surface of the die pad 100 or the lead 101 of the lead frame 10 is not tightly attached to the lower mold of the package molding equipment, a glue overflow 130 will appear as shown in FIG. 1.

This excess glue overflow will cause the lead bumps of the QFN semiconductor package to be unequal and abnormal, thereby leading to problems such as short circuits and poor contacts in eventual electronic elements. Furthermore, for the removal (De-flash) of glue overflow, most manufacturers choose manual removal solutions. However, manual glue removal not only takes a long time, but also has the problem of glue overflow that is difficult to remove. Therefore, how to overcome the shortcomings of the prior art is actually an urgent technical problem to be solved.

### SUMMARY

In view of the various deficiencies of the prior art, the present disclosure provides a detection equipment used to detect whether a semiconductor device is provided with a patch, which comprises: a color sensor configured for performing color analysis and sampling of the patch via multiple light sources, so as to identify the patch by using a proportion of color components of light reflected by the patch; and a control device configured for connecting the color sensor for receiving an activation signal of the color sensor and generating a detection value, wherein if the detection value is greater than a preset value, it is determined that the semiconductor device is provided with the patch, and wherein if the detection value is less than the preset value, it is determined that the semiconductor device is not provided with the patch.

The present disclosure further provides a detection method that uses a detection equipment to detect whether a semiconductor device is provided with a patch, comprising: using multiple light sources to conduct color analysis and sampling of the patch via a color sensor of the detection equipment, so as to identify the patch by using a proportion of color components of light reflected by the patch; and receiving an activation signal of the color sensor and generating a detection value via a control device of the detection equipment, wherein if the detection value is greater than a preset value, it is determined that the semiconductor device is provided with the patch, and wherein if the detection value is less than the preset value, it is determined that the semiconductor device is not provided with the patch.

In the aforementioned detection equipment and method, the detection equipment is defined with a feed area, an operating area and an outfeed area, and wherein a patch supply device and a patch cutter are provided in the feed area, an operating platform is provided in the operating area, and the color sensor and the control device are provided in the outfeed area.

In the aforementioned detection equipment and method, the patch supply device in the feed area of the detection equipment provides a full roll of patches, and the patch cutter cuts the full roll of patches to obtain a plurality of patches with required dimension for placing the patches with required dimension on the operating platform in the operating area.

In the aforementioned detection equipment and method, the semiconductor device is moved to the operating platform in the operating area via a robotic arm to allow the patch attached to the semiconductor device.

In the aforementioned detection equipment and method, the semiconductor device is moved to a conveyor platform in the outfeed area via a robotic arm, wherein the color sensor and the control device are provided under the conveyor platform to detect whether the patch is actually attached to the semiconductor device.

In the aforementioned detection equipment and method, a wavelength range of the multiple light sources is between 380 nm to 750 nm.

To sum up, in the detection equipment and detection method of the present disclosure, a patch is provided at the bottom of the lead frame where the die placement and wiring are completed, and at the same time, the proportion of light and color components reflected via the color sensor and control device can be used to instantly detect whether the patch is actually attached under the lead frame, so as to avoid glue overflow on the die pad or leads of the lead frame during subsequent package molding, which may cause abnormal appearance of the molded product and cause it to be scrapped.

### BRIEF DESCRIPTION OF THE DRAWINGS

FIG. 1 is a schematic view showing the problem of glue overflow in a conventional QFN electronic package.

FIG. 2 is a partial schematic view of a detection equipment according to the present disclosure.

FIG. 3 is a schematic flow chart illustrating a detection method according to the present disclosure.

FIG. 4 is a partial schematic view of a feed area of the detection equipment according to the present disclosure.

FIG. 5A and FIG. 5B are partial schematic views of an operating area of the

detection equipment according to the present disclosure.

FIG. 6 is a partial schematic view of an outfeed area of the detection equipment according to the present disclosure.

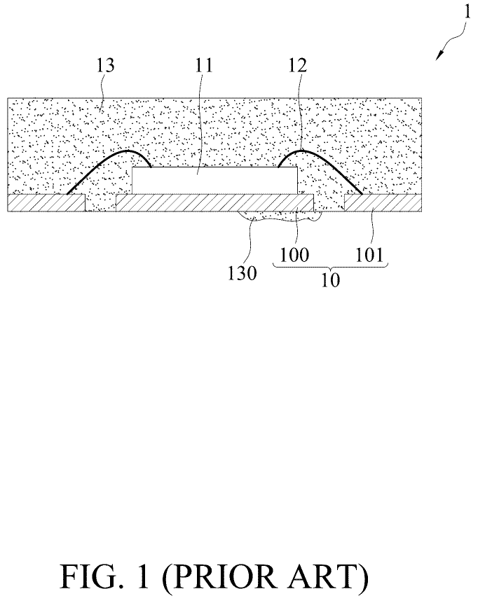

### DETAILED DESCRIPTIONS

The following describes the implementation of the present disclosure with examples. Those skilled in the art can easily understand other advantages and effects of the present disclosure from the contents disclosed in this specification.

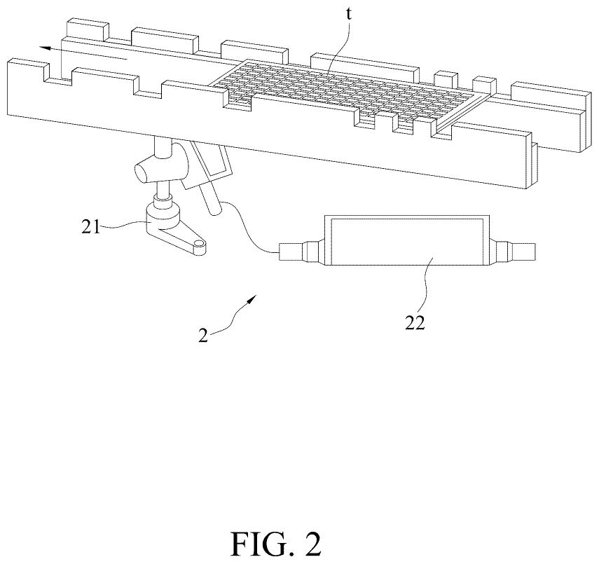

FIG. 2 is a partial schematic view of a detection equipment 2 of the present disclosure, which includes a color sensor 21 and a control device 22.

The detection equipment 2 of the present disclosure is mainly used in the semiconductor packaging process, for example, to detect a semiconductor device t of a QFN semiconductor package, wherein the detection equipment 2 mainly sets a patch on a lead frame after completing the die placement and wiring, and detects whether the patch is effectively adhered to the lead frame, so as to avoid glue overflow problems on a die pad or leads of the lead frame during subsequent package molding.

The aforementioned color sensor 21 is able to perform die color analysis and sampling via multiple light sources with a wide wavelength range. Using the proportion of light and color components reflected by the patch, the difference between the presence and absence of the patch can be effectively identified.

Furthermore, the color sensor 21 mainly uses multiple light sources (RGB spectrum) with a wide wavelength range (between 380 nm to 750 nm) to effectively identify whether there is a patch on the lead frame. Compared with the use of optical fiber sensors, which are limited to a single light source (red light) with a small wavelength range (between 620 nm to 750 nm), the optical fiber sensors are only able to detect the amount of light reflected by the material, but has no ability to identify whether there is a missing patch. Accordingly, the present disclosure can increase the detection capability of no patch and prevent the product from overflowing/underfilling/residual glue in the mold after packaging molding and causing quality abnormalities, thereby avoiding the loss of product scrapping and reduce the problem of manual removal of residual glue, and improving the machine utilization rate.

The aforementioned control device 22 is, for example, a hardware and/or a firmware and/or a software (such as a control die, a control software or a controller), depending on the actual implementation situation. The control device 22 is electrically/communicatively connected to the color sensor 21 for receiving the activation signal of the color sensor 21 and providing a feedback signal. During the actual manufacturing process, the control device 22 presets a value, and then the semiconductor device t is detected via the color sensor 21 to generate a detection signal and provide the detection signal to the control device 22 to allow the control device 22 to generate a detection value and compares the detection value with the preset value. If the detection value is greater than the preset value, it is determined that there is a patch provided on the semiconductor device t. If the detection value is less than the preset value, it is determined that there is no patch provided on the semiconductor device t. Then, an alert notification will be sent to the operator for confirmation and remediation.

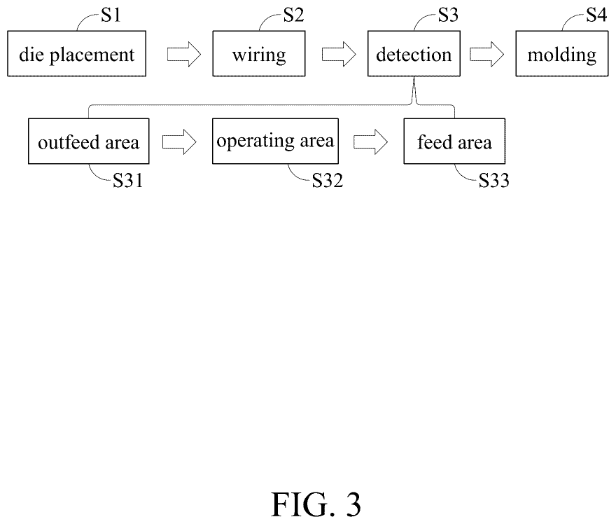

Please refer to FIG. 3 at the same time, which is a detection method using the aforementioned detection equipment 2 of the present disclosure. The aforementioned detection method is mainly a schematic process diagram, which is used to detect whether the patch is effectively placed before a molding operation when the lead frame of a QFN semiconductor package is undergoing operations such as die placement, wire bonding, and molding.

In step S1: a die placement operation is performed. A one-piece lead frame is provided, wherein the one-piece lead frame includes a plurality of lead frames, each of the lead frames has a die pad and a plurality of leads to allow at least one semiconductor die to be placed on the die pad of the lead frame.

In step S2: a wiring operation is performed. The semiconductor die and the plurality of leads are electrically connected via a plurality of bonding wires.

In step S3: a detection operation is performed. During the detection operation, the one-piece lead frame that has completed the die placement and wiring operations is moved to a semiconductor detection equipment to allow a patch to be placed on the one-piece lead frame and a detection is performed.

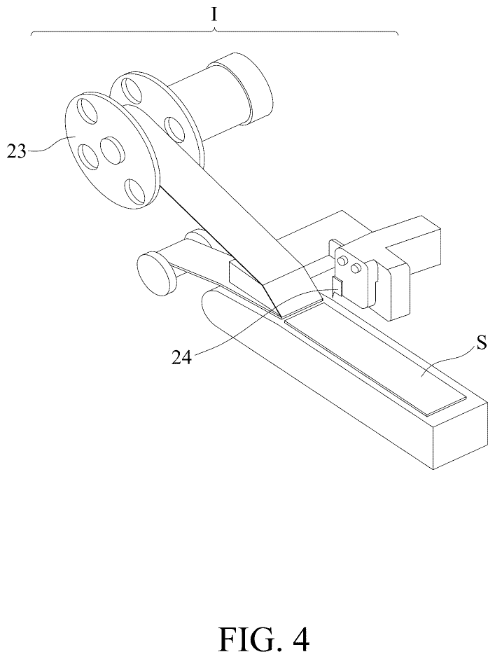

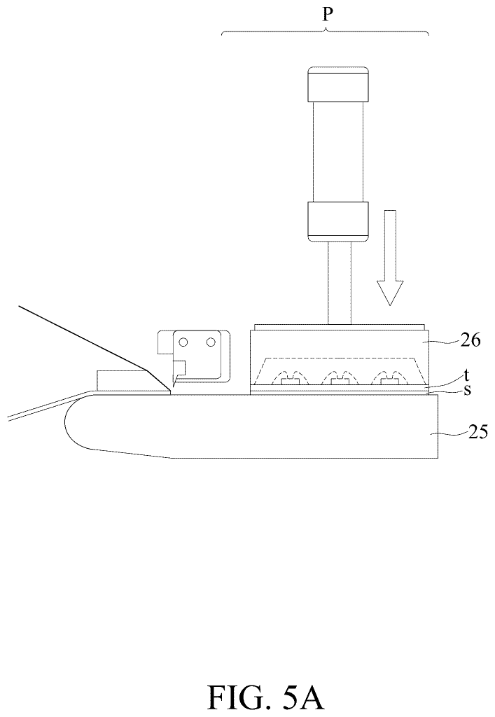

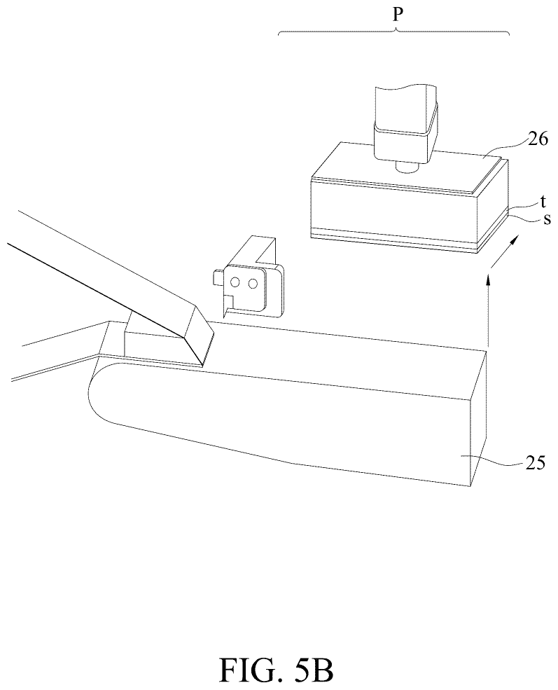

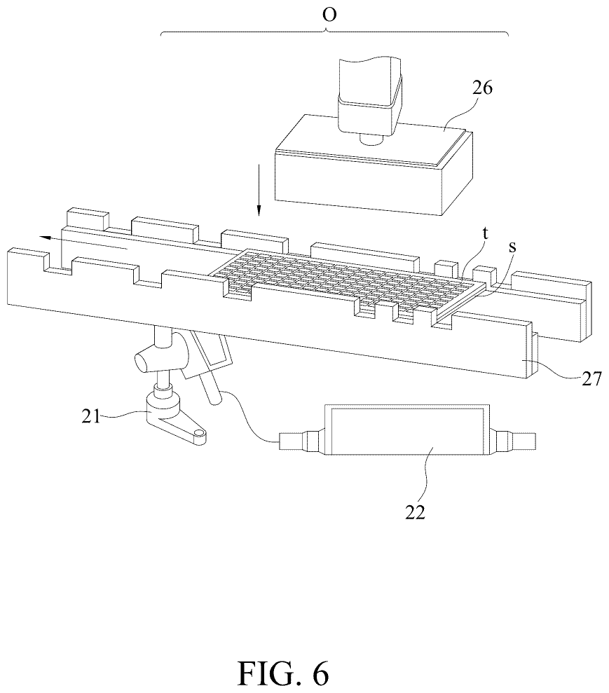

Please refer to FIG. 4, FIG. 5A, FIG. 5B and FIG. 6 at the same time. The detection equipment 2 is planned with

a feed area I, an operating area P and an outfeed area O. The feed area I is provided with a patch supply device 23 and a patch cutter 24, the operating area P is provided with an operating platform 25, and the outfeed area O is provided with the aforementioned color sensor 21 and control device 22.

In step S31: a patch preparation operation is performed. The patch supply device 23 in the feed area I of the detection equipment 2 provides a full roll of patches, and the patch cutter 24 cuts a patch with required dimension for providing a patch s cut with the required dimension on the operating platform 25 of the operating area P.

In step S32: a patch setting operation is performed. The one-piece lead frame (the semiconductor device t) that has completed the die placement and wiring operations is moved to the operating platform 25 of the operating area P via a robot arm 26 to allow the patch s to be attached to the one-piece lead frame.

In step S33: a patch detection operation is performed. The one-piece lead frame (the semiconductor device t) that has completed the aforementioned patch setting operation is moved to a conveyor platform 27 (such as an outfeed track) in the outfeed area O via the robot arm 26. The aforementioned color sensor 21 and control device 22 are provided below the conveyor platform 27 to accurately detect whether the patch is actually attached below the one-piece lead frame. If not, a warning notification is issued.

In step S4: a molding operation is performed. The one-piece lead frame that has completed the aforementioned patch detection operation is packaged and molded to allow an encapsulating colloid to cover the semiconductor die and the bonding wires is formed on the one-piece lead frame.

To sum up, in the detection equipment and detection method of the present disclosure, a patch is provided at the bottom of the lead frame where the die placement and wiring are completed, and at the same time, the proportion of light and color components reflected via the color sensor and control device can be used to instantly detect whether the patch is actually attached under the lead frame, so as to avoid glue overflow on the die pad or leads of the lead frame during subsequent package molding, which may cause abnormal appearance of the molded product and cause it to be scrapped.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A detection equipment, used to detect whether a semiconductor device is provided with a patch, comprising:
a color sensor, configured for performing color analysis and sampling of the patch via multiple light sources, so as to identify the patch by using a proportion of color components of light reflected by the patch; and
a control device, configured for connecting the color sensor for receiving an activation signal of the color sensor and generating a detection value, wherein if the detection value is greater than a preset value, it is determined that the semiconductor device is provided with the patch, and wherein if the detection value is less than the preset value, it is determined that the semiconductor device is not provided with the patch.

2. The detection equipment of claim 1, which is defined with a feed area, an operating area and an outfeed area.

3. The detection equipment of claim 2, wherein a patch supply device and a patch cutter are provided in the feed area.

4. The detection equipment of claim 3, wherein an operating platform is provided in the operating area.

5. The detection equipment of claim 4, wherein the color sensor and the control device are provided in the outfeed area.

6. The detection equipment of claim 5, wherein the patch supply device provides a full roll of patches, and the patch cutter cuts the full roll of patches to obtain a plurality of patches with required dimension for placing the patches with required dimension on the operating platform in the operating area.

7. The detection equipment of claim 6, wherein the semiconductor device is moved to the operating platform in the operating area via a robotic arm for attaching the patch to the semiconductor device.

8. The detection equipment of claim 7, wherein the semiconductor device is moved to a conveyor platform in the outfeed area via a robotic arm after completing a placement operation of the patch, and the color sensor and the control device are provided under the conveyor platform to detect whether the patch is actually attached to the semiconductor device.

9. The detection equipment of claim 1, wherein a wavelength range of the multiple light sources is between 380 nm to 750 nm.

10. A detection method that uses a detection equipment to detect whether a semiconductor device is provided with a patch, comprising:
using multiple light sources to conduct color analysis and sampling of the patch via a color sensor of the detection equipment, so as to identify the patch by using a proportion of color components of light reflected by the patch; and
receiving an activation signal of the color sensor and generating a detection value via a control device of the detection equipment, wherein if the detection value is greater than a preset value, it is determined that the semiconductor device is provided with the patch, and wherein if the detection value is less than the preset value, it is determined that the semiconductor device is not provided with the patch.

11. The detection method of claim 10, wherein the detection equipment is defined with a feed area, an operating area and an outfeed area, wherein the feed area is provided with a patch supply device and a patch cutter, the operating area is provided with an operating platform, and the outfeed area is provided with the color sensor and the control device.

12. The detection method of claim 11, further comprising: providing a full roll of patches via the patch supply device in the feed area of the detection equipment, and cutting the full roll of patches by the patch cutter to obtain a plurality of patches with required dimension for placing the patches with required dimension on the operating platform in the operating area.

13. The detection method of claim 12, further comprising: moving the semiconductor device to the operating platform in the operating area via a robotic arm for attaching the patch to the semiconductor device.

14. The detection method of claim 13, further comprising: moving the semiconductor device to a conveyor platform in the outfeed area via a robotic arm, wherein the color sensor and the control device are provided under the conveyor platform to detect whether the patch is actually attached to the semiconductor device.

15. The detection method of claim 10, wherein a wavelength range of the multiple light sources is between 380 nm to 750 nm.
